(19) United States
(12) Patent Application Publication
(10) Pub. No.: US 2026/0231384 A1
(43) Pub. Date: Aug. 6, 2026

(54) FEEDER MANAGEMENT DEVICE

(71) Applicant: FUJI CORPORATION, Chiryu (JP)

(72) Inventor: Kohei SUGIHARA, Nishio-shi (JP)

(73) Assignee: FUJI CORPORATION, Chiryu (JP)

(21) Appl. No.: 19/152,293

(22) PCT Filed: Feb. 8, 2023
(86) PCT No.: PCT/JP2023/004105

§ 371 Date: Jul. 30, 2025

(51) Int. Cl. H05K 13/08; H05K 13/04

(52) U.S. Cl. CPC H05K 13/086; H05K 13/043

(57) ABSTRACT

A feeder management device includes: an acquisition section configured to acquire a feeder ID of a bulk feeder installed in a component mounter and a unit ID of a conveyance unit that is detachably set in a feeder main body of the bulk feeder and forms a conveyance path for a component; and a determination section configured to, based on the feeder ID and the unit ID acquired by the acquisition section, determine whether to permit or restrict application of the bulk feeder to a mounting process by the component mounter.

### TECHNICAL FIELD

The present disclosure relates to a feeder management device.

### BACKGROUND ART

The feeder management device manages a bulk feeder as a management target. The bulk feeder is installed in a component mounter for mounting components on a board, and is used for supplying the components. As disclosed in Patent Literature 1, the bulk feeder supplies components in a bulk state in a supply region where a suction nozzle of the component mounter can collect the components. When the type of components supplied by the bulk feeder is changed, maintenance, such as removing the components remaining in the feeder, is performed as appropriate in addition to replacing a component case.

### CITATION LIST

### Patent Literature

Patent Literature 1: WO 2021/095219

### BRIEF SUMMARY

### Technical Problem

The bulk feeder includes a type in which a conveyance unit is configured to be detachable from a feeder main body and includes a component conveyance path. In such a type, while maintainability is improved, when there is an error in the combination of the feeder main body and the conveyance unit, there is a concern that a mounting process may fail to be executed normally.

An object of the present description is to provide a feeder management device that performs management, including a conveyance unit set in a bulk feeder installed in a component mounter, to support execution of a normal mounting process.

### Solution to Problem

The present description discloses a feeder management device including: an acquisition section configured to acquire a feeder ID of a bulk feeder installed in a component mounter and a unit ID of a conveyance unit that is detachably set in a feeder main body of the bulk feeder and forms a conveyance path for a component; and a determination section configured to, based on the feeder ID and the unit ID acquired by the acquisition section, determine whether to permit or restrict application of the bulk feeder to a mounting process by the component mounter.

### Advantageous Effects

With such a configuration, the bulk feeder installed in the component mounter is managed, including the conveyance unit set in the bulk feeder, so that execution of a normal mounting process can be supported.

### BRIEF DESCRIPTION OF DRAWINGS

FIG. 1 is a schematic diagram illustrating a production system to which a feeder management device and a setup device are applied.

FIG. 2 is a plan view schematically illustrating a component mounter.

FIG. 3 is a side view schematically illustrating a part of a bulk feeder including a supply region.

FIG. 4 is a plan view as viewed from an IV direction in FIG. 3.

FIG. 5 is a perspective view illustrating an appearance of a conveyance unit and the setup device constituting the bulk feeder.

FIG. 6 is a block diagram illustrating the setup device.

FIG. 7 is a diagram illustrating unit information, feeder information, and case information.

FIG. 8 is a flowchart illustrating a feeder management process.

### DESCRIPTION OF EMBODIMENTS

### 1. Overview of Feeder Management Device 80

Feeder management device 80 manages a feeder that supplies components to component mounter 2, as a target. In the present embodiment, feeder management device 80 is incorporated into control device 96 of component mounter 2, and into host computer 70 serving as a host device that manages multiple board work machines including component mounter 2. Feeder management device 80 manages bulk feeder 10, which is a type of feeder, as a management target.

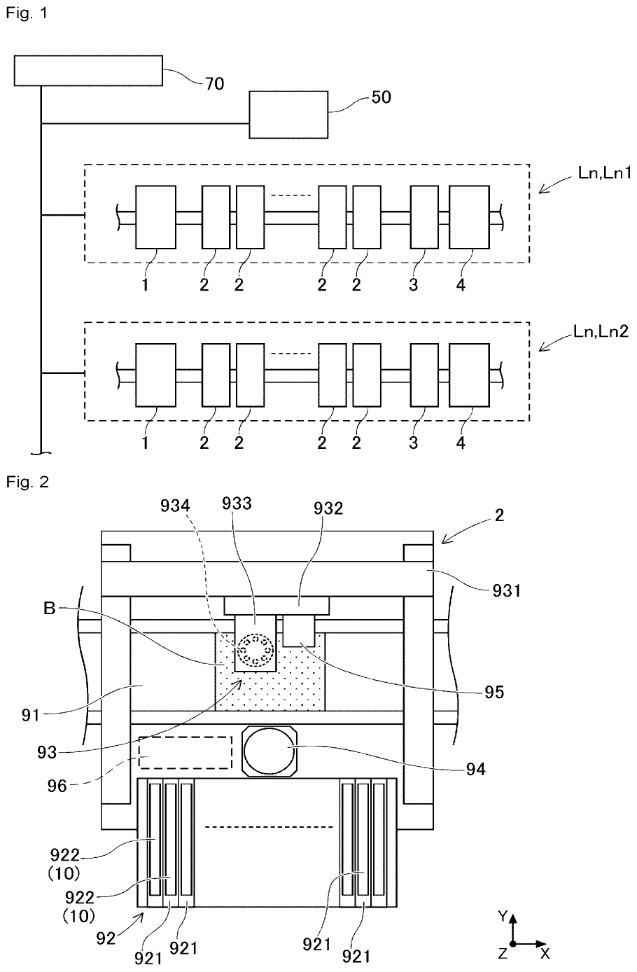

Component mounter 2 described above executes a mounting process of mounting components on a board as a predetermined board work. As illustrated in FIG. 1, production line Ln is formed by arranging multiple board work machines in a conveyance direction of the board. Each of the multiple board work machines is communicably connected with host computer 70, which collectively controls production line Ln. Production line Ln includes printer 1, multiple component mounters 2, reflow oven 3, and inspector 4 as multiple board work machines.

Printer 1 prints paste-like solder at mounting positions of components on the board that has been conveyed in. Each of multiple component mounters 2 mounts components on the board conveyed from an upstream side of production line Ln. The configuration of component mounter 2 will be described later. Reflow oven 3 heats the board conveyed from the upstream side of production line Ln, melts the solder on the board, and performs soldering. Inspector 4 inspects whether an appearance or a function of the board product produced by production line Ln is normal.

In the present embodiment, a factory for producing the board product may be configured with multiple production lines Ln (Ln1, Ln2, . . . ) . The configuration of each of multiple production lines Ln can be appropriately equipped with additional configurations or can be appropriately modified in accordance with, for example, the type of board product to be produced. Specifically, a board work machine such as a buffer device for temporarily holding the board conveyed, a board supply device, a board flipping device, various types of inspection devices, a shield mounting device, an adhesive application device, an ultraviolet ray irradiation device, or the like can be installed in multiple production lines Ln as appropriate.

Setup device 50 is used for work of loading components into a feeder used for a mounting process scheduled to be executed, work of detaching components from a feeder used for the mounting process, and the like. Setup device 50 includes support table 51 that supports the feeder or a part of units detached from the feeder. Setup device 50 is communicably connected to host computer 70, and receives and outputs various information relating to setup. A detailed configuration of setup device 50 will be described later.

### 2. Configuration of Component Mounter 2

### 2-1. Board Conveyance Device 91

As illustrated in FIG. 2, component mounter 2 includes board conveyance device 91. Board conveyance device 91 subsequently conveys board B in a conveyance direction and positions board B at a predetermined position within the mounter.

### 2-2. Component Supply Device 92

Component mounter 2 includes component supply device 92. Component supply device 92 supplies components to be mounted on board B. In component supply device 92, feeders 922 are respectively set in multiple slots 921. For example, a tape feeder that feeds and moves a carrier tape accommodating a large number of components to supply the components such that the components can be collected is applied to feeder 922. In addition, bulk feeder 10 that supplies components accommodated in a bulk state such that the components can be collected is applied to feeder 922. Details of bulk feeder 10 will be described below.

### 2-3. Component Transfer Device 93

Component mounter 2 includes component transfer device 93. Component transfer device 93 transfers components supplied by component supply device 92 to predetermined mounting positions on board B. Component transfer device 93 includes head drive device 931, moving table 932, mounting head 933, and suction nozzle 934. Head drive device 931 moves moving table 932 in a horizontal direction (X direction and Y direction) by a linear motion mechanism. Mounting head 933 is detachably fixed to moving table 932 by a clamp member (not illustrated), and is provided to be movable in the horizontal direction within the mounter.

Mounting head 933 supports multiple suction nozzles 934 rotatably, liftably, and lowerably. Suction nozzle 934 is a holding member that collects and holds a component supplied by feeder 922. Suction nozzle 934 picks up the component supplied by feeder 922 using supplied negative pressure air. As a holding member to be attached to mounting head 933, a chuck or the like that holds a component by gripping the component can be adopted.

### 2-4. Part Camera 94 and Board Camera 95

Component mounter 2 includes part camera 94 and board camera 95. Part camera 94 and board camera 95 are digital imaging devices having imaging elements, such as CMOS. Part camera 94 and board camera 95 perform imaging based on control signals and transmit image data acquired by the imaging. Part camera 94 is configured to image a component held by suction nozzle 934 from below. Board camera 95 is provided on moving table 932 to be movable in the horizontal direction integrally with mounting head 933. Board camera 95 is configured to image board B from above.

In addition to using a surface of board B as an imaging target, board camera 95 can use various devices or the like as the imaging target as long as various devices are within a movable range of moving table 932. For example, in the present embodiment, as illustrated in FIG. 4, board camera 95 can image supply region As to which bulk feeder 10 supplies components or fiducial marks 39 provided on an upper portion of bulk feeder 10 within the camera's field of view. As described above, board camera 95 can be used to image different imaging targets in order to acquire the image data used for various pieces of image processing.

### 2-5. Control Device 96

As illustrated in FIG. 2, component mounter 2 includes control device 96. Control device 96 mainly includes CPU and various types of memories, a control circuit, and a storage device. Various data, such as a control program used for controlling a mounting process, are stored in control device 96. The control program indicates the mounting position, mounting angle, and component type of the components to be mounted on board B in the mounting process in the scheduled mounting order.

Control device 96 executes recognition processing of a holding state of the component held by each of multiple holding members (suction nozzles 934). Specifically, control device 96 executes image processing on image data acquired through imaging by part camera 94 and recognizes a position and an angle of each component with respect to a reference position of mounting head 933. In addition to part camera 94, control device 96 may execute the image processing on the image data acquired by imaging the component by a head camera unit or the like provided integrally with mounting head 933 from side, below, or above.

### 3. Configuration of Bulk Feeder 10

Bulk feeder 10, which is the target of management by feeder management device 80 will be described. Bulk feeder 10 is installed in component mounter 2 and functions as a part of the component supply device. Bulk feeder 10 supplies components accommodated in a bulk state, in which the components are not aligned as in a carrier tape (in an irregular state in which respective postures thereof are not regular). Therefore, since bulk feeder 10 does not use the carrier tape unlike the tape feeder, there is an advantage in that loading of the carrier tape, retrieving of the used tape, or the like can be omitted.

For example, there is bulk feeder 10 of a type that supplies components in irregular postures to planar supply region As. However, when the components are so close to one another to contact, the components are accumulated (a state of being overlapped in an up-down direction), or the components are in a horizontally standing posture in which a width direction of the components is directed in the up-down direction in supply region As, component mounter 2 cannot regard these components as a collection target. Then, in order to increase the ratio of components that can be collected, there is bulk feeder 10 of a type that supplies components in an aligned state to supply region As. In the present embodiment, bulk feeder 10 of the type which aligns the components will be described as an example.

### 3-1. Feeder Main Body 11

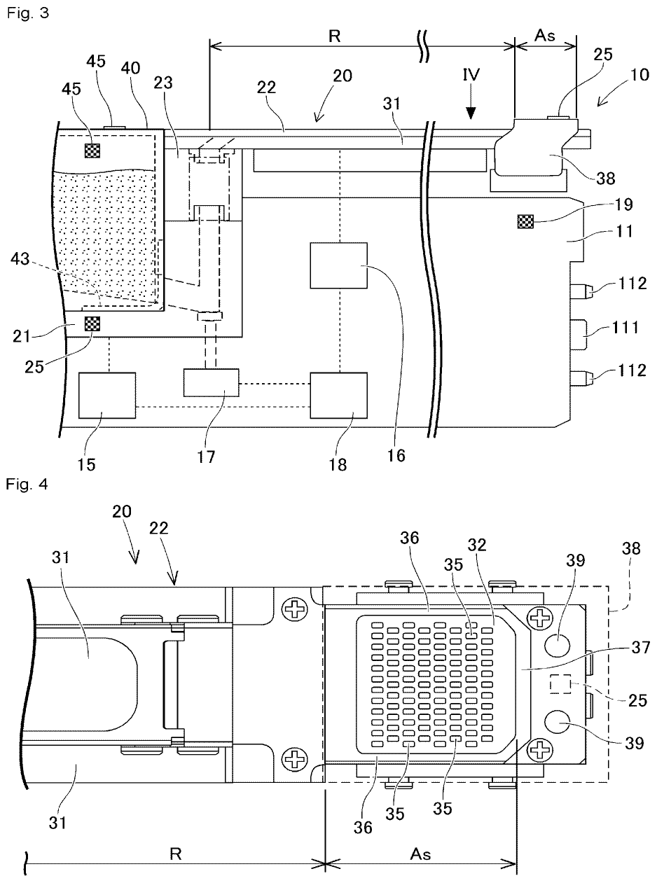

As illustrated in FIG. 3, bulk feeder 10 includes feeder main body 11. Feeder main body 11 is formed into a flat box shape. Connector 111 and two pins 112 are provided on a front portion (the right side end portion in FIG. 3) of feeder main body 11. When feeder main body 11 is set in slot 921 of component supply device 92, power is supplied via connector 111 and feeder main body 11 is in a communicable state with control device 96 of component mounter 2. Two pins 112 are inserted into guide holes provided in slot 921 to thereby be used to position feeder main body 11 when feeder main body 11 is set in slot 921.

### 3-2. Conveyance Unit 20

As illustrated in FIG. 3, bulk feeder 10 includes conveyance unit 20. Conveyance unit 20 is detachably attached to feeder main body 11. Conveyance unit 20 supports set component case 40 to be described later. Conveyance unit 20 is a unit for conveying components from a region for receiving the components discharged from component case 40 to supply region As.

After bulk feeder 10 is used for a predetermined mounting process, removal work to remove all components inside the feeder in preparation for next use is performed as a type of maintenance. Conveyance unit 20 is configured to be detachable from feeder main body 11 as a unit that functions as a flow path for components in order to improve efficiency, assuming the above-described removal work. In the present embodiment, conveyance unit 20 includes case support member 21, track unit 22, and coupling member 23.

Case support member 21 is provided to be capable of vibrating with respect to feeder main body 11. Case support member 21 is vibrated by first vibration device 15 described later. Case support member 21 supports set component case 40. Case support member 21 receives the components discharged from component case 40. In the present embodiment, the portion of case support member 21 that receives the components has an inclined surface inclined to the front side with respect to a horizontal surface. Case support member 21 is formed with a flow path for components that extends upward from a lower end portion of the inclined surface.

Track unit 22 is provided to be capable of vibrating with respect to feeder main body 11. Track unit 22 is vibrated by second vibration device 16 described later. Track unit 22 is formed with conveyance path R through which multiple components are conveyed, and supply region As that communicates with conveyance path R and is open upward such that the multiple components can be collected. Here, “supply region As” is a region in which components are supplied in a bulk state, and is a region in which components can be collected by component mounter 2. The “conveyance path R” is a path for components in which components flowing from case support member 21 side to track unit 22 are conveyed to supply region As.

Track unit 22 is formed so as to extend in a front-rear direction (the left-right direction in FIG. 3) of feeder main body 11 as an overall shape. In the present embodiment, track unit 22 is configured such that alignment member 32 is replaceably attached to track main body 31. Alignment member 32 is, for example, one or multiple plate-shaped members. Track unit 22 is a track member that is unitized by attaching one alignment member 32 selected from multiple types of alignment members 32 corresponding to the shape of multiple types of components to common track main body 31.

As illustrated in FIG. 4, alignment member 32 forms multiple cavities 35 arranged in a predetermined pattern (in a zigzag pattern in the present embodiment). Each of multiple cavities 35 has a rectangular shape slightly larger than the outer shape of the components supplied by bulk feeder 10. As described above, bulk feeder 10 includes multiple cavities 35 in which the components are accommodated in a posture in which the thickness direction of the components is the up-down direction in supply region As to which the components are supplied such that the components can be collected. Pair of side walls 36, which protrudes upward, is formed along both edges in the width direction (the up-down direction in FIG. 4) of track unit 22. Pair of side walls 36 surrounds the peripheral edge of conveyance path R together with distal end portion 37 of track unit 22 to prevent leakage of the components conveyed through conveyance path R.

Shutter 38 capable of closing the opening of supply region As is provided on an upper portion of track unit 22. When track unit 22 is attached to feeder main body 11, shutter 38 is in a state in which opening and closing operations of shutter 38 are controlled by a shutter drive device (not illustrated). By opening or closing shutter 38, bulk feeder 10 can prevent components from protruding and foreign matters from entering supply region As.

Coupling member 23 couples case support member 21 and track unit 22 such that multiple components can flow therebetween. Coupling member 23 has a tubular shape in which the multiple components can flow inside. Coupling member 23 has flexibility and absorbs each vibration by being deformed according to the vibration of case support member 21 and the vibration of track unit 22. Accordingly, coupling member 23 reduces or blocks vibration transmitted between case support member 21 and track unit 22 that vibrate independently of each other.

When attached to feeder main body 11, conveyance unit 20 is supplied with positive pressure air by air supply device 17, and causes the multiple components to flow from case support member 21 to track unit 22 via coupling member 23. In the present embodiment, air supply device 17 supplies or blocks the positive pressure air, which is supplied from the outside, from below case support member 21, based on a command from feeder control device 18 described later.

### 3-3. First Vibration Device 15 and Second Vibration Device 16

Bulk feeder 10 includes first vibration device 15 and second vibration device 16 provided in feeder main body 11. First vibration device 15 applies vibration to case support member 21 to promote the discharge of the components from set component case 40. Second vibration device 16 applies vibration to track unit 22 so that the multiple components are conveyed along conveyance path R. When second vibration device 16 applies vibration to track unit 22, track unit 22 performs an elliptical motion in a lateral view.

As a result, a forward and upward external force or a rearward and upward external force is applied to the multiple components in conveyance path R in accordance with a rotational direction of the elliptical motion of track unit 22. As a result, the multiple components are conveyed to the front side or the rear side of track unit 22. Bulk feeder 10 can vary the conveyance speed of components to be conveyed, the degree of dispersion of components, the conveyance direction, and the like by controlling the frequency and amplitude of the vibration applied to track unit 22, and the rotational direction of the elliptical motion caused by the vibration.

### 3-4. Feeder Control Device 18

Bulk feeder 10 includes feeder control device 18. Feeder control device 18 mainly includes CPU, various memories, and a control circuit. Feeder control device 18 is supplied with power via connector 111 in a state in which bulk feeder 10 is set in the slot of component mounter 2, and is in a communicable state with the control device of component mounter 2.

Various data, such as a program used for controlling a component supply process or a conveyance parameter, are stored in feeder control device 18. The “conveyance parameter” described above is a parameter for controlling the operation of second vibration device 16 so that the vibration applied to track unit 22 is appropriate when components are conveyed in the component supply process, and is set in advance in association with each type of component, for example.

Feeder control device 18 controls operations of first vibration device 15, second vibration device 16, air supply device 17, the shutter drive device, and the like. For example, feeder control device 18 controls the operation of second vibration device 16 based on a parameter set in advance to execute the component supply process. Accordingly, vibration is applied to track unit 22, and the components on conveyance path R are conveyed by receiving the external force to move in the conveyance direction.

### 3-5. Component Case 40

Component case 40 accommodates multiple components in a bulk state. Component case 40 is an external device that is replaceably set on case support member 21 in conveyance unit 20 of bulk feeder 10. Component case 40 includes case main body 41 formed in a flat box shape similarly to feeder main body 11.

### 4-1. Component Supply Process of Bulk Feeder 10

A component supply process by bulk feeder 10 configured as described above will be described. First, feeder control device 18 discharges components from component case 40 based on, for example, a supply command from the outside. Specifically, feeder control device 18 controls the operation of first vibration device 15 so that vibration is applied to case support member 21 to which component case 40 is attached. When component case 40 vibrates, components are discharged from a discharge port. The discharged components drop to an inclined portion of case support member 21 positioned below the discharge port and slide forward along the inclined surface of the inclined portion. Accordingly, the components stay at the lower end portion in front of the inclined portion.

In this state, feeder control device 18 commands air supply device 17 to supply the positive pressure air. The positive pressure air supplied from air supply device 17 blows up the multiple staying components, and flows through the flow path formed in case support member 21 together with the components. As a result, the positive pressure air and the multiple components flow from case support member 21 to track unit 22 via coupling member 23, and reach conveyance path R of track unit 22. Here, the positive pressure air is exhausted to the outside from an exhaust port formed in the cover of track unit 22.

Thereafter, when second vibration device 16 for component conveyance applies vibration to track unit 22, the multiple components are conveyed to supply region As side. In addition, vibration for moving the components forward or backward is applied to track unit 22 in accordance with the supply amount of components in supply region As, or the like. Some of the multiple components conveyed to supply region As are accommodated in cavities 35. The components that are not accommodated in cavities 35 are further moved backward to conveyance path R by the vibration applied by second vibration device 16, and are removed from supply region As. With the component supply process, the components accommodated in multiple cavities 35 are supplied in a state in which the components can be collected by component mounter 2.

### 4-2. Identification Information of Bulk Feeder 10 and Component Case 40

In the present embodiment, identification codes indicating respective identification information (unique ID) are attached to bulk feeder 10 and component case 40. Since the present embodiment adopts the configuration in which conveyance unit 20 is replaceable with respect to feeder main body 11, unit code 25 is attached to conveyance unit 20 as an identification code. In the present embodiment, unit code 25 is a 2D code indicating a unit ID, and as illustrated in FIGS. 3 and 4, is attached to a side surface of case support member 21 and an upper surface of shutter 38.

Case code 45 is attached to component case 40 as an identification code. In the present embodiment, case code 45 is a 2D code indicating a case ID, and as illustrated in FIGS. 3 and 4, is attached to a side surface and an upper surface of case main body 41, respectively. Unit code 25 and case code 45 may be barcodes, or may be codes to which RFID is applied. The feeder ID, which is the identification information of bulk feeder 10, is recorded in feeder control device 18 and transmitted via communication with an external device. An identification code (feeder code 19) indicating the feeder ID may be attached to feeder main body 11, for example.

### 5. Setup Device 50

### 5-1. Overview of Setup Device 50

Setup device 50 is installed, for example, in an off-line setup area between a warehouse for storing components (not illustrated) or the like and production line Ln in a production facility of a product board. In the off-line setup area, work of loading components such that various types of feeders can supply components can be automatically performed by setup device 50, or can be manually performed by a worker. Further, setup device 50 supports a part of the work of loading components into the feeder. Between the off-line setup area and the warehouse, and between the off-line setup area and production line Ln, an automated guided vehicle or the worker can convey feeders or components.

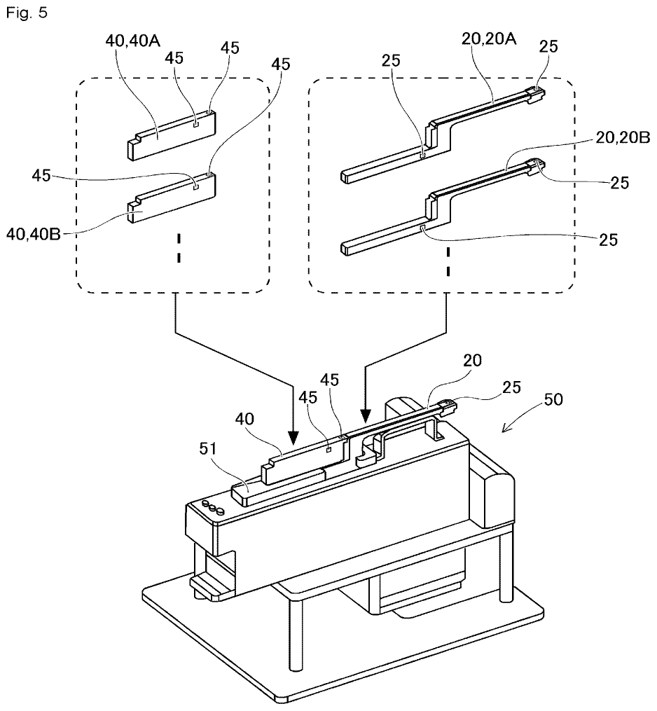

In the present embodiment, as illustrated in FIG. 5, setup device 50 sets component case 40 in conveyance unit 20 detached from bulk feeder 10, and supports the work of achieving a state in which conveyance unit 20 causes the components to flow. In addition, the setup work includes work of associating set component case 40 with conveyance unit 20 and recording the combination thereof in host computer 70.

Here, conveyance unit 20 differs in the types of components compatible with the supply (compatible component type) depending on the type of alignment member 32 of track unit 22, specifically, the shape of cavity 35. This is because, depending on the shape of the component and the shape of cavity 35, the component is not accommodated in cavity 35 or is not aligned appropriately even if accommodated in cavity 35. That is, conveyance unit 20 is classified according to the compatible component type as an example, and is selected according to the type of component to be supplied in the mounting process.

Component case 40 is classified according to the type of components to be accommodated (accommodated component type), and is selected according to the type of components to be supplied in the mounting process. Conveyance unit 20 and component case 40 may be classified according to the functions and characteristics of conveyance unit 20 and component case 40 in addition to or instead of the compatible component type and the accommodation component type.

### 5-2. Configuration of Setup Device 50

As illustrated in FIG. 5, setup device 50 includes support table 51. Support table 51 supports conveyance unit 20 detached from feeder main body 11 of bulk feeder 10. Support table 51 has a support structure similar to the support structure of feeder main body 11, and supports case support member 21 and track unit 22 of conveyance unit 20.

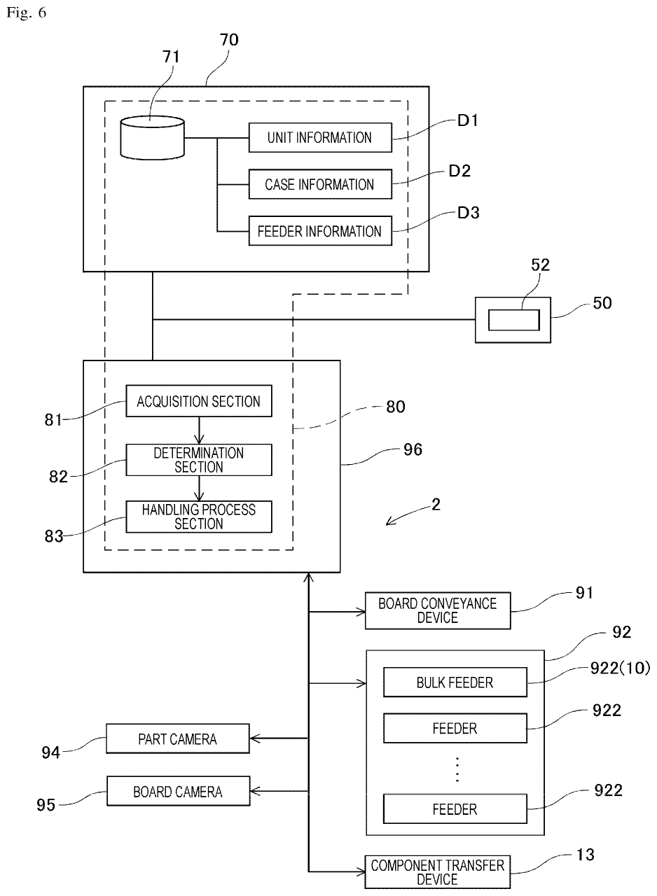

As illustrated in FIG. 6, setup device 50 includes code reader 52. Code reader 52 reads unit code 25 of conveyance unit 20 and case code 45 of component case 40, and acquires the identification information (unit ID, case ID). Code reader 52 may be, for example, a hand scanner, or may be configured to perform reading when conveyance unit 20 or component case 40 is positioned at a predetermined position with respect to support table 51.

When the setup work using setup device 50 is performed, the case ID is associated with the unit ID acquired by code reader 52 and transmitted to host computer 70. As illustrated in FIG. 6, the associated information between the unit ID and the case ID is recorded as case information D2 in storage section 71 of host computer 70.

In addition, conveyance unit 20, to which component case 40 is attached, is set in predetermined feeder main body 11. As a result, bulk feeder 10 is loaded with the components discharged from component case 40 and is in a state in which the components can be supplied. The work of setting conveyance unit 20 in feeder main body 11 is performed in the off-line setup area or the like. When conveyance unit 20 is set in feeder main body 11, the unit ID is associated with the feeder ID and transmitted to host computer 70. As illustrated in FIG. 6, the associated information between the feeder ID and the unit ID is recorded as unit information D1 in storage section 71 of host computer 70. The feeder ID attached to feeder main body 11 is acquired via communication between an external device and feeder control device 18 or by reading an identification code (feeder code 19), such as a 2D code attached to feeder main body 11.

### 6. Feeder Management Device 80

### 6-1. Overview of Feeder Management Device 80

Here, in bulk feeder 10 of the type in which conveyance unit 20 is configured to be detachable from feeder main body 11 as described above, for example, when conveyance unit 20, to which component case 40 is attached, is set in feeder main body 11 and then replaced with another conveyance unit 20 offline, the components to be supplied change. As described above, when there is an error in the combination of feeder main body 11 and conveyance unit 20, there is a concern that the supply of different types of components may occur, and the mounting process may fail to be executed normally.

Therefore, in the present embodiment, a configuration is adopted in which feeder management device 80, incorporated into control device 96 and host computer 70, performs management, including conveyance unit 20 set in bulk feeder 10 installed in component mounter 2, to support execution of a normal mounting process. Specifically, feeder management device 80 includes acquisition section 81 and determination section 82, as illustrated in FIG. 6. In the present embodiment, feeder management device 80 includes handling process section 83 and storage section 71.

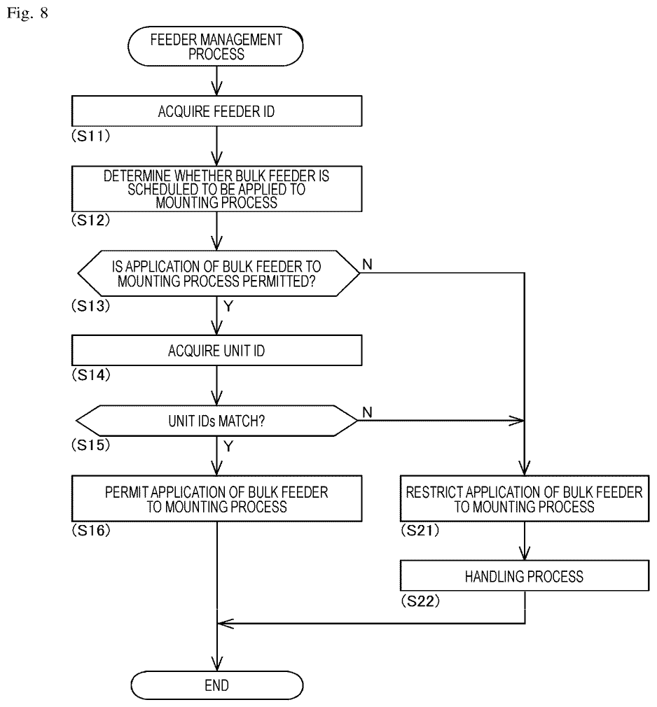

Feeder management device 80 executes a feeder management process illustrated in FIG. 8. Hereinafter, each step of feeder management process and detailed description of each configuration of feeder management device 80 will be described in association with each other. The feeder management process is executed, for example, when bulk feeder 10 is installed in slot 921 of component mounter 2, power is supplied to bulk feeder 10, and control device 96 and feeder control device 18 are in a communicable state.

### 6-2. Acquisition Section 81

Acquisition section 81 acquires the feeder ID of bulk feeder 10 installed in component mounter 2 and the unit ID of conveyance unit 20 set in bulk feeder 10. In the present embodiment, when bulk feeder 10 is installed in component mounter 2 and is in a communicable state, acquisition section 81 acquires the feeder ID via communication with bulk feeder 10 (S11).

In addition, after bulk feeder 10 has been installed in component mounter 2 and before the mounting process is executed, acquisition section 81 acquires the unit ID by imaging, with a camera (board camera 95 in the present embodiment), unit code 25 attached to conveyance unit 20, specifically, unit code 25 attached to the upper surface of shutter 38 and reading unit code 25 (S14). Acquisition section 81 may acquire each of the feeder ID and the unit ID via communication or by reading using the camera or wireless communication.

Furthermore, acquisition section 81 may acquire the case ID of component case 40 in addition to the feeder ID and the unit ID. For example, similarly to the unit ID, acquisition section 81 can acquire the case ID indicated by case code 45 by imaging case code 45 attached to the upper surface of component case 40 by board camera 95. Here, it is assumed that component case 40 attached to conveyance unit 20 has not been replaced since setup, and the acquisition of the case ID is omitted.

### 6-3. Determination Section 82

Determination section 82 determines, based on the feeder ID and the unit ID acquired by acquisition section 81, whether to permit or restrict application of bulk feeder 10 to the mounting process by component mounter 2. Various aspects can be adopted for the determination process of applicability by determination section 82. Specifically, determination section 82 may determine, based on unit information D1, whether the unit ID associated with the feeder ID during setup matches the unit ID of conveyance unit 20 currently attached to feeder main body 11.

Here, in the present embodiment, when bulk feeder 10 is installed in component mounter 2, it is determined whether bulk feeder 10 is to be used or applicable to the mounting process scheduled to be executed. The determination process described above is executed by host computer 70 that collectively manages production line Ln. Feeder information D3 in addition to unit information D1 and case information D2 is stored in storage section 71 of host computer 70.

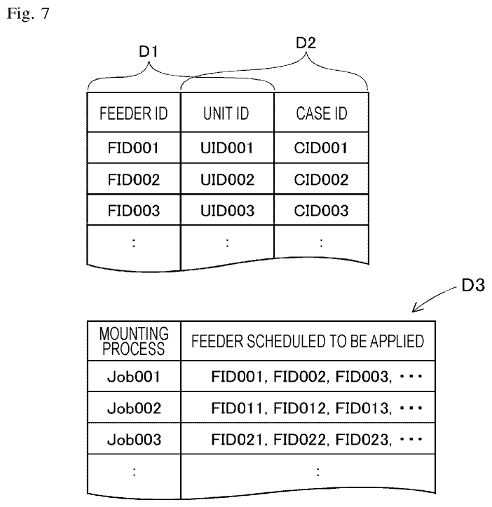

As illustrated in FIG. 7, feeder information D3 indicates the feeder ID of bulk feeder 10 scheduled to be applied for each mounting process scheduled to be executed in multiple component mounters 2. That is, for each mounting process scheduled to be executed, the feeder ID of bulk feeder 10 to be used or applicable is set in advance. Then, host computer 70 receives the feeder ID via communication from component mounter 2 in which bulk feeder 10 is installed, and executes the determination process.

Specifically, host computer 70 determines, based on the received feeder ID and feeder information D3, whether bulk feeder 10 is scheduled to be applied to the mounting process scheduled to be executed in component mounter 2 in which bulk feeder 10 is installed (S12). When the received feeder ID is included in the application of the corresponding mounting process scheduled to be executed in feeder information D3, host computer 70 determines that bulk feeder 10 is scheduled to be applied. To the contrary, when the received feeder ID is not included in feeder information D3, host computer 70 determines that bulk feeder 10 is not applicable.

Host computer 70 returns the determination result to component mounter 2 that has transmitted the feeder ID. In this case, when the determination result indicates that bulk feeder 10 is scheduled to be applied, host computer 70 outputs the unit ID corresponding to the feeder ID based on unit information D1. When component mounter 2 receives the determination result from host computer 70 as to whether bulk feeder 10 is scheduled to be applied, and the determination result indicates that bulk feeder 10 is scheduled to be applied, component mounter 2 receives the corresponding unit ID. In addition to the unit ID, the case ID may also be added to the determination result.

When host computer 70 permits the application of bulk feeder 10 (S13: Yes), acquisition section 81 executes a feeder ID acquisition process as described above (S14). Then, determination section 82 transmits the feeder ID to host computer 70 to receive the unit ID based on unit information D1, that is, the unit ID associated with the feeder ID during setup, and compares the received unit ID with the feeder ID acquired by acquisition section 81, that is, the unit ID of conveyance unit 20 set in bulk feeder 10 actually installed in component mounter 2 (S15).

When the unit ID corresponding to the feeder ID acquired by acquisition section 81 is acquired from unit information D1 and the unit ID matches the unit ID acquired by acquisition section 81 (S15: Yes), determination section 82 permits the application of bulk feeder 10 to the mounting process (S16). Accordingly, control device 96 of component mounter 2 issues an execution request for the component supply process to bulk feeder 10 and executes a collection operation for the components supplied by bulk feeder 10, during the execution of the mounting process.

When the case ID is acquired in the acquisition process (S14) by acquisition section 81 and the determination result from host computer 70 is received with the case ID added, determination section 82 may additionally include these case IDs as targets of the comparison process (S15) to determine whether the case IDs match. In the aspect as described above, determination section 82 determines, based on the feeder ID, the unit ID, and the case ID acquired by acquisition section 81, whether to permit or restrict application of bulk feeder 10 to the mounting process by component mounter 2.

### 6-4. Handling Process Section 83

When the application of bulk feeder 10 installed in component mounter 2 to the mounting process is restricted (S21), handling process section 83 executes a predetermined handling process (S22). Specifically, in the present embodiment, when host computer 70 does not permit the application of bulk feeder 10 (S13: No), or when the unit ID corresponding to the feeder ID (acquired from unit information D1 via host computer 70) does not match the unit ID acquired by acquisition section 81 (S15: No), determination section 82 restricts the application of bulk feeder 10 to the mounting process by component mounter 2 (S21).

In the present embodiment, as the handling process, handling process section 83 notifies the worker that bulk feeder 10 is not applicable to the mounting process scheduled to be executed, and restricts the execution of the mounting process. Accordingly, the worker can recognize that incorrect conveyance unit 20 is set in bulk feeder 10 installed in component mounter 2, and is prompted to perform maintenance. Further, since the execution of the mounting process is restricted, it is possible to prevent the mounting process using bulk feeder 10 that may supply an incorrect type of component from being executed.

### 7. Effects of Configuration of Embodiment

With such a configuration, bulk feeder 10 installed in component mounter 2 is managed, including conveyance unit 20 set in bulk feeder 10, so that execution of a normal mounting process can be supported.

### 8. Modifications of Embodiment

In the embodiment, feeder management device 80 is configured to be incorporated into component mounter 2 and host computer 70. Meanwhile, a part or the entirety of feeder management device 80 may be incorporated into component mounter 2, host computer 70, and other external devices. For example, the entirety of feeder management device 80 may be incorporated into component mounter 2 or host computer 70, or may be provided as a dedicated device installed in production line Ln.

In the embodiment, bulk feeder 10 supplies components to be mounted on the board by component mounter 2. Meanwhile, the components are used in a board work machine which performs predetermined work on the board as in component mounter 2, and various types of components can be applied as long as the articles can be supplied in a state of being accommodated in cavities 35 in the bulk feeder. For example, bulk feeder 10 may supply a solder ball formed in a spherical shape. Even in such an aspect, effects similar to those of the embodiment are obtained.

### REFERENCE SIGNS LIST

2: component mounter, 10: bulk feeder, 11: feeder main body, 19: feeder code (identification code), 20, 20A, 20B: conveyance unit, 21: case support member, 22: track unit, 25: unit code (identification code), 40, 40A, 40B: component case, 41: case main body, 45: case code (identification code), 70: host computer (host device), 71: storage section, 80: feeder management device, 81: acquisition section, 82: determination section, 83: handling process section, D1: unit information, D2: case information, D3: feeder information, As: supply region, R: conveyance path

1. A feeder management device comprising:
an acquisition section configured to acquire a feeder ID of a bulk feeder installed in a component mounter and a unit ID of a conveyance unit that is detachably set in a feeder main body of the bulk feeder and forms a conveyance path for a component; and
a determination section configured to, based on the feeder ID and the unit ID acquired by the acquisition section, determine whether to permit or restrict application of the bulk feeder to a mounting process by the component mounter.

2. The feeder management device according to claim 1, further comprising:
a storage section configured to store unit information in which the unit ID of the conveyance unit set in the feeder main body is associated with the feeder ID as setup for the mounting process,
wherein, when the unit information corresponding to the feeder ID acquired by the acquisition section is acquired from the storage section and the unit ID included in the unit information matches the unit ID acquired by the acquisition section, the determination section permits the application of the bulk feeder to the mounting process.

3. The feeder management device according to claim 2,
wherein the storage section is provided in an external host device configured to manage the component mounter, and
when the feeder ID acquired by the acquisition section is received, the host device outputs the unit ID corresponding to the feeder ID based on the unit information.

4. The feeder management device according to claim 3,
wherein the storage section stores feeder information indicating the feeder ID of the bulk feeder scheduled to be applied for each mounting process scheduled to be executed in multiple component mounters, and
the host device determines, based on the received feeder ID and the feeder information, whether the bulk feeder is scheduled to be applied to the mounting process scheduled to be executed in the component mounter in which the bulk feeder is installed, and when a determination result indicates that the bulk feeder is scheduled to be applied, the host device outputs the unit ID.

5. The feeder management device according to claim 2,
wherein the storage section stores case information in which a case ID of a component case attached to the conveyance unit is associated with the unit ID,
the acquisition section acquires the case ID of the component case attached to the conveyance unit of the bulk feeder installed in the component mounter, and
the determination section determines, based on the feeder ID, the unit ID, and the case ID acquired by the acquisition section, whether to permit or restrict the application of the bulk feeder to the mounting process by the component mounter.

6. The feeder management device according to claim 1, wherein the acquisition section acquires the feeder ID or the unit ID via communication with the bulk feeder installed in the component mounter or by reading a code attached to the bulk feeder.

7. The feeder management device according to claim 1, wherein, when the bulk feeder is installed in the component mounter and is in a communicable state, the acquisition section acquires the feeder ID via communication with the bulk feeder.

8. The feeder management device according to claim 1, wherein, after the bulk feeder is installed in the component mounter and before the mounting process is executed, the acquisition section acquires the unit ID by imaging, with a camera, a code attached to the conveyance unit and reading the code.

9. The feeder management device according to claim 1, further comprising:
a handling process section configured to, when the application of the bulk feeder installed in the component mounter to the mounting process is restricted, execute a predetermined handling process.

10. The feeder management device according to claim 9, wherein, as the handling process, the handling process section notifies a worker that the bulk feeder is not applicable to the mounting process scheduled to be executed, and restricts execution of the mounting process.
